(19) United States
(12) Patent Application Publication
(10) Pub. No.: US 2025/0109479 A1
(43) Pub. Date: Apr. 3, 2025

(54) ANTI-CORROSION AND ANTI-FOULING TREATMENT FOR STEEL AND STEEL PREPARED THEREFROM

(71) Applicant: Rodney Herring, Victoria (CA)

(72) Inventor: Rodney Herring, Victoria (CA)

(21) Appl. No.: 18/890,670

(22) Filed: Sep. 19, 2024

(30) Foreign Application Priority Data
Sep. 29, 2023 (CA) 3214984

(51) Int. Cl. C23C 14/08; C23C 14/02; C23C 14/14

(52) U.S. Cl. CPC C23C 14/083; C23C 14/021; C23C 14/14

(57) ABSTRACT

A method of manufacturing an anti-corrosion steel from a selected article of steel is provided, the selected article of steel including an outer surface, the method comprising: treating the outer surface to produce a dislocation zone in the selected article of steel that extends inward 10 to 20 micrometers from the outer surface; corroding the outer surface and the dislocation zone to a depth of no more than 20 micrometers from the outer surface to provide a controlled corroded steel layer comprising goethite and akaganéite; binding titanium dioxide to the goethite and akaganéite to provide an alloyed layer; and depositing silicon dioxide on the alloyed layer, thereby manufacturing the anti-corrosion steel.

### CROSS REFERENCE TO RELATED APPLICATIONS

The present application claims benefit of Canadian Patent Application Serial No. 3,214,984, filed on Sep. 29, 2023, entitled ANTI-CORROSION AND ANTI-FOULING TREATMENT FOR STEEL AND STEEL PREPARED THEREFROM, the contents of which are incorporated herein by reference.

### FIELD

The present technology is directed to an anti-corrosion treatment involving oxidizing steel to produce a layer of goethite and akaganeite, then binding titanium dioxide to the goethite and akageneite, followed by binding silicon dioxide to the titanium dioxide. The anti-fouling treatment involves binding low iron oxide, iron doped titanium dioxide to the silicon dioxide.

### BACKGROUND

In many environments, corrosion of steel is a major problem. This is especially true in marine environments. The hulls and many other parts of ships are steel, and over time, these rust, eventually leading to the ships being decommissioned and scraped. This happens more quickly on the ocean, leading to shorter life spans of the ships referred to as “Salties”. There are many approaches to reducing corrosion of steel. For example, European Patent Application No. 1990437 discloses that anti-corrosion steel for ship is provided at low cost, which exhibits excellent corrosion resistance without depending on a surface condition of steel even under severe corrosion environment such as a ballast tank of a ship. Anti-corrosion steel for ship contains, in mass percent, C of 0.03 to 0.25%, Si of 0.05 to 0.50%, Mn of 0.1 to 2.0%, P of 0.025% or less, S of 0.01% or less, Al of 0.005 to 0.10%, W of 0.01 to 1.0%, Cr of 0.01% or more and less than 0.20%, and furthermore contains as needed one or two selected from Sb of 0.001 to 0.3% and Sn of 0.001 to 0.3% and/or one or at least two selected from Ni of 0.005 to 0.25%, Mo of 0.01 to 0.5%, and Co of 0.01 to 1.0%, and contains the remainder including Fe and inevitable impurities. It is known that these steels still rust.

European Patent No. 0096526 discloses that anti-corrosion coating comprises a pigment salt (I) dispersed in a binder, (I) comprising a polyvalent metal cation (II) and an organic polyphosphonic acid (III) contain. at least two phosphonic acid groups, the mol. ratio of (II) to (III) being at least 0.8/n:1 where n=valency of the metal ion. Pref. (I) has the formula M(x)R(PO3)(m)H(2m−Xn), where M=Zn, Mn, Mg, Ca, Ba, Al, Co, Fe, Sr, Sn, Zr, Ni, Cd or Ti; R=organic radical linked by C—P bonds; m=valency of R (at least 2); n=valency of M and x=0.8 m/n to 2 m/n. Process is used for coating iron and steel structural components etc. Coating affords better rusting protection than Zn phosphate whilst avoiding chemicals which are health hazards. This is a coating and does not chemically bond to the steel.

European Patent Application No. 1514910 discloses a primary anti-corrosive paint composition comprising (a) a zinc dust, (b) an amorphous glass powder containing an alkali metal oxide as a compositional component, (c) a siloxane type coupling agent and (d) an organic solvent. Also disclosed is a steel plate with primary anti-corrosive paint film wherein a steel plate is coated with the primary anti-corrosive paint composition. The primary anti-corrosive paint composition is capable of forming a paint film which does not lower anti-corrosion properties and can Inhibit occurrence of defects such as pits or blowholes even if welding is carried out at a high speed of not less than 100 cm/min. This is a coating and does not chemically bond to the steel.

WO/2021/243771 discloses an anti-corrosion system, a preparation method therefor, and an anti-corrosion coating, the anti-corrosion system comprising a first functional layer wrapping a protected matrix, wherein the first functional layer contains a fluorine-containing piezoelectric material, and the first functional layer may generate dynamic response current under a stress condition so as to prevent corrosive ions from being transmitted to the protected matrix. The transmission process of corrosive ions in the anti-corrosion system may be actively regulated and controlled by the anti-corrosion system provided by the present invention, and the permeation effect of the corrosive ions in the anti-corrosion system is markedly relieved. Further provided by the present invention is the preparation method for the anti-corrosion system and an application of the anti-corrosion system in a corrosive environment. Meanwhile, also provided by the present invention is the anti-corrosion coating. After the coating is dried to form a coating layer, dynamic response current may be generated under the stress condition so as to prevent corrosive ions from being transmitted to the protected matrix, and the permeation effect of the corrosive ions in the coating layer is markedly relieved. This is a coating and does not chemically bond to the steel.

U.S. Pat. No. 4,443,503 discloses an anti-corrosive coating composition comprising (a) 100 parts by weight of an unsaturated polyester resin, (b) 10 to 100 parts by weight of a glass flake having an average thickness of 0.5 to 5 micrometers and an average particle size of 100 to 400 micrometers, or 10 to 70 parts by weight of said glass flake and 10 to 150 parts of scaly metal pigment, (c) 0.1 to 1.0 part by weight of a ketone peroxide and (d) 0.5 to 2.0 parts by weight of a hydroperoxide and/or a peroxy ester. Also disclosed is a process for forming anti-corrosive coatings, which comprises spray-coating the above anti-corrosive coating composition to a thickness of 300 to 1500 micrometers by using a spray gun having a spray tip diameter of 0.5 to 3 mm. This is a coating and does not chemically bond to the steel.

With regard to anti-fouling in a marine environment, many approaches involve the use of chemicals that are harmful to the environment. For example, United States Patent Application Publication No. 20070137546 discloses systems and processes for controlling and/or preventing fouling of marine vessel hulls and fixed structures are disclosed. The systems and processes deliver an anti-fouling composition through a dispersing means, such as dispersion tubing, to the surface of a vessel hull or fixed structure below the water line. Also disclosed are methods of controlling the delivery of an anti-fouling composition to the surface of a vessel hull or fixed structure below the waterline, including the steps of generating signals representative of parameters such as current flow direction and speed and water temperature, to identify and control the proper volume release rate of the anti-fouling solution.

A more recent patent application, United States Patent Application Publication No. 20210017402 discloses materials such as a coating, an elastomer, an adhesive, a sealant, a textile finish, a wax, and a filler for such a material, wherein the material includes a proteinaceous molecule such as a peptide and/an enzyme that confer a metal binding, an anti-fouling and/or an antibiotic property to the material. In particular, disclosed herein are marine coatings such as a marine paint that comprise an anti-fouling peptide sequence that reversibly binds a metal cation that is toxic to a fouling organism. Also disclosed herein are methods of reducing fouling on a surface by treating the surface with a metal binding peptide. Unfortunately, the metals used are copper or nickel, both which are toxic.

It is known that one cannot coat steel with glass as the glass (silicon dioxide) and steel have different atomic lattice parameters resulting in poor atomic bonding and significant strain. Additionally, steel and glass have very different thermal expansion coefficients. These mismatches make steel and glass incompatible.

What is needed is a method that would allow silicon dioxide to be used as an anti-corrosion treatment for steel. It would be further preferable if the anti-corrosion surface could also provide an anti-fouling surface.

### SUMMARY

The present technology is a method that allows silicon dioxide to be used as an anti-corrosion treatment for steel. The method first provides a layer of rust that is primarily goethite and akageneite. The layer is confined to 10 to 20 micrometers in thickness. Titanium dioxide integrates into the rust, binding with the goethite and akageneite to provide a surface to which silicon dioxide is bound. This provides the anti-corrosion surface. The silicon dioxide can be functionalized with low iron oxide, iron doped titanium dioxide nanoparticles to provide an anti-corrosion, anti-fouling surface.

In one embodiment a method of manufacturing an anti-corrosion steel from a selected article of steel is provided, the selected article of steel including an outer surface, the method comprising: treating the outer surface to produce a dislocation zone in the selected article of steel that extends inward 10 to 20 micrometers from the outer surface; corroding the outer surface and the dislocation zone to a depth of no more than 20 micrometers from the outer surface to provide a controlled corroded steel layer comprising goethite and akaganéite; binding titanium dioxide to the goethite and akaganéite to provide an alloyed layer; and depositing silicon dioxide on the alloyed layer, thereby manufacturing the anti-corrosion steel.

In the method, the treating may be abrading the outer surface of the selected article of steel to provide scratched steel.

In the method, the abrading may be with 5 to 10 micrometer grit.

In the method, the corroding and binding titanium dioxide may be concomitant.

In the method, the corroding may precede the binding of titanium dioxide.

The method may further comprise cleaning at least one rust deposit on the outer surface of the selected article of steel prior to treating the outer surface to produce the dislocation zone.

In the method, the anti-corrosion steel may also be an anti-fouling steel, and the method may further comprise functionalizing the silicon dioxide of the anti-corrosion steel with iron doped titanium dioxide nanoparticles to provide anti-corrosion, anti-fouling steel.

The method may further comprise acid washing the functionalized silicon dioxide of the anti-corrosion, anti-fouling steel to provide low iron oxide, iron doped titanium dioxide functionalized silicon dioxide.

In the method, the anti-corrosion steel may also be an anti-fouling steel, and the method may further comprise functionalizing the silicon dioxide of the anti-corrosion steel with low iron oxide, iron doped titanium dioxide.

In the method, the functionalizing may be by sputter deposition of high purity iron and titanium dioxide on the silicon dioxide.

In another embodiment, an anti-corrosion steel is provided, the anti-corrosion steel comprising, in order: a silicon dioxide layer; an alloyed layer including goethite, akaganéite and titanium dioxide which is bound to the goethite and the akaganéite; and an uncorroded inner layer.

In the anti-corrosion steel, the alloyed layer may be up to 20 micrometers in depth.

In another embodiment, an anti-corrosion, anti-fouling steel is provided, the anti-corrosion, anti-fouling steel comprising: an iron doped titanium dioxide functionalized silicon dioxide layer; an alloyed layer including goethite, akaganéite and titanium dioxide which is bound to the goethite and the akaganéite; and an uncorroded inner layer.

In the anti-corrosion, anti-fouling steel, the alloyed layer may be up to 20 micrometers in depth.

In the anti-corrosion, anti-fouling steel, the iron doped titanium dioxide functionalized silicon dioxide may be low iron oxide, iron doped titanium dioxide-silicon dioxide.

### BRIEF DESCRIPTION OF THE DRAWINGS

FIG. 1 is a schematic showing the results of scratching the surface of the steel, which is the first step in all the methods.

FIGS. 2A-C are schematics of the subsequent method of producing the anti-corrosion steel of the present technology. FIG. 2A shows the steel with scratches and the corroded layer; FIG. 2B shows titanium dioxide binding to the goethite and akaganéite in the corroded layer to provide an alloyed layer; FIG. 2C shows silicon dioxide binding to the titanium dioxide; and FIG. 2D shows the anti-corrosion steel.

FIGS. 3A-D are schematics of the subsequent method of producing the anti-corrosion, anti-fouling steel of the present technology. FIG. 3A shows the steel with scratches and the corroded layer; FIG. 3B shows titanium dioxide binding to the goethite and akaganéite in the corroded layer to provide an alloyed layer; FIG. 3C shows a silicon dioxide layer binding to the alloyed layer; FIG. 3D shows silicon dioxide binding to the titanium dioxide layer binding to the silicon dioxide layer to provide the anti-corrosion, anti-fouling steel of the present technology.

FIGS. 4A-C are schematics of an alternative method of producing the anti-corrosion, antifouling steel of the present technology, following the scratching step. FIG. 4A shows the steel with dislocations and the corroded layer; FIG. 4B shows titanium dioxide binding to the goethite and akaganéite in the corroded layer to provide an alloyed layer; and FIG. 4C shows a silicon dioxide-low iron oxide, titanium dioxide nanoparticle layer binding to the alloyed layer to provide the anti-corrosion, anti-fouling steel of the present technology.

### DETAILED DESCRIPTION

Except as otherwise expressly provided, the following rules of interpretation apply to this specification: (a) all words used herein shall be construed to be of such gender or number (singular or plural) as the circumstances require; (b) the singular terms “a”, “an”, and “the”, as used in the specification and the appended claims include plural references unless the context clearly dictates otherwise; (c) the antecedent term “about” applied to a recited range or value denotes an approximation within the deviation in the range or value known or expected in the art from the measurements method; (d) the words “herein”, “hereby”, “hereof”, “hereto”, “hereinbefore”, and “hereinafter”, and words of similar import, refer to this specification in its entirety and not to any particular paragraph, claim or other subdivision, unless otherwise specified; (e) descriptive headings are for convenience only and shall not control or affect the meaning or construction of any part of the specification; and (f) “or” and “any” are not exclusive and “include” and “including” are not limiting. Further, the terms “comprising,” “having,” “including,” and “containing” are to be construed as open-ended terms (i.e., meaning “including, but not limited to,”) unless otherwise noted.

Recitation of ranges of values herein are merely intended to serve as a shorthand method of referring individually to each separate value falling within the range, unless otherwise indicated herein, and each separate value is incorporated into the specification as if it were individually recited herein. Where a specific range of values is provided, it is understood that each intervening value, to the tenth of the unit of the lower limit unless the context clearly dictates otherwise, between the upper and lower limit of that range and any other stated or intervening value in that stated range, is included therein. All smaller sub ranges are also included. The upper and lower limits of these smaller ranges are also included therein, subject to any specifically excluded limit in the stated range.

Unless defined otherwise, all technical and scientific terms used herein have the same meaning as commonly understood by one of ordinary skill in the relevant art. Although any methods and materials similar or equivalent to those described herein can also be used, the acceptable methods and materials are now described.

### Definitions:

Physical vapour deposition—in the context of the present technology, physical vapour deposition includes, but is not limited to, magnetron sputtering, ion beam sputtering, reactive sputtering, ion assist deposition, high target utilization sputtering, pulsed laser deposition and gas flow sputtering.

Thin film—in the context of the present technology, a thin film is up to 5 micrometers in thickness. A film may be a partial coating, a deposit upon a surface, a complete coating or a plurality of layers. To be clear, gaps may occur where the surface below is exposed. It may be formed by, for example, but not limited to growing nanocrystals on the substrate, physical vapour deposition on the substrate or photolithography on the substrate.

Iron-doped titanium dioxide with a low iron oxide surface—in the context of the present technology, iron-doped titanium dioxide with a low iron oxide surface has about 0.1 atomic % iron to about 2.0 atomic % iron, preferably 0.25 atomic % iron to about 0.75 atomic % iron, and more preferably 0.5 atomic % iron and very small amounts of iron oxide on its surface (less than 5% of the surface being iron oxide) when viewed with X-ray photoelectron spectroscopy.

Substantially iron oxide free surface—in the context of the present technology, a substantially iron oxide free surface has an iron oxide content corresponding to less than about 0.001% atomic iron (less than 0.5% of the surface being iron oxide) when viewed with X-ray photoelectron spectroscopy.

Dislocation—in the context of the present technology a dislocation is a crystallographic defect or irregularity within a crystal structure. Dislocations are sites that are prone to corrosion and extend into the steel as pits or tunnels. These can be also considered as surface discontinuities.

Selected article of steel—in the context of the present technology a selected article of steel may be for example, but not limited to a steel plate, a reinforcing bar, a steel deck, steel decking, a ship's hull and the like.

### Detailed Description:

The overall basis of the anti-corrosion treatment is that dislocations created by grinding are sites of corrosion. Scratching the surface of a material creates dislocations inside the material. In alternative embodiments, dislocations are created by ion implanting the steel with heavy atoms such as Gallium or Nitrogen or shot pinging the steel.

Without being bound to theory, the role of the dislocations in corrosion is providing energy and a pathway (mechanism) for penetration of the corrosion into the material. When dislocations approach a surface, they transform from a linear defect to a 3-dimensional defect forming a pit on the surface. Surfaces can't hold strain so the strain of the dislocation is released forming the 3-dimensional pit. The pit aids corrosion by reducing the number of atomic bonds of the atoms inside of the pit with their neighbours. For example, atoms on the surface of a material lose one atomic bond because there is no atom above. In the pit, there is no atom above and no atom towards the inside of the pit. This makes the atoms inside the pit more vulnerable to reacting with corrosion species like OH—ions, Cl—, etc. Thus, the atoms inside the pit readily oxidize. When they oxidize, they nucleate and grow an oxide crystal. The oxide crystal has a different oxidation potential than the host material enhancing its continued growth. The oxide crystal grows by a standard crystal growth mechanism. The oxide crystal grows into the material within the pit along the path provided by the dislocation. The dislocation is constantly transforming from a linear defect (one dimensional) to a 3-dimensional defect, i.e., the pit, increasing the depth of the pit inside the material helping the oxide crystal grow into the material. The dislocation also releases its strain energy as it's forming the pit that helps the growth of the oxide crystal. By increasing the number and density of dislocations at and near the surface of the material, enhanced oxidation is achieved. Scratching the surface of the material produces dislocations and thus significantly enhances controlled corrosion.

If properly controlled, these sites of corrosion primarily consist of goethite and akaganéite. It was found that titanium dioxide binds to goethite and akaganéite to produce an alloyed surface. Subsequent binding of silicon dioxide to the alloyed surface provides a protective layer that reduces or eliminates further corrosion.

In one embodiment rusty steel was cleaned of rust and other contamination by means such as scrapping or wire brushing. This was followed by grinding and polishing the steel to produce scratches. The polishing started with millimeter sizes and worked down to micrometer size grits. Each reduction in grit size reduced the scratches created by the previous larger grit. Eventually, the scratches on the surface of the steel were equal to the grit size of the polish. The preferred dislocation depth was between about 10 micrometers to about 20 micrometers. The scratches produce dislocations inside the steel extended to two times the grit size, hence the preferred grit size was about 5 micrometers to about 10 micrometers. The steel with dislocations was referred to as scratched steel.

In another embodiment, freshly smelted steel was the starting material, hence the steel was ground and polished to produce dislocations. Again, the polishing started with millimeter sizes and worked down to micrometer size grits. Each reduction in grit size reduced the scratches created by the previous larger grit. Eventually, the scratches on the surface of the steel were equal to the grit size of the polish. The preferred dislocation depth was between about 10 micrometers to about 20 micrometers. The scratching produced dislocations inside the steel extending to two times the grit size, hence the preferred grit size was about 5 micrometers to about 10 micrometers. The steel with dislocations was referred to as scratched steel.

The scratched steel was then corroded to produce controlled corrosion steel. In one embodiment, corroding was effected by a steam treatment. The scratched steel was then corroded to produce controlled corrosion steel. In one embodiment, corroding was effected by a steam treatment at 100° C. to 500° C. and preferably 400° C. At 400° C. the corrosion occurs in about one second.

In another embodiment, corroding was effected by treating the scratched steel with an aqueous sodium chloride solution. The sodium chloride can be as low as 5 parts per million.

In another embodiment, the corroding was effected by treating the scratched steel with an aqueous calcium chloride solution. The calcium chloride can be as low as 5 parts per million.

In another embodiment, the scratched steel was treated with a 5% NaCl+0.4% (NH₄)₂SO₄ acidic water solution spray for one hour, then dried for one hour daily for seven days at 25° C. The timing and the oxidizing conditions used were selected to produce goethite (α-FeOOH) and akaganéite (β-FeOOH). As goethite and akaganéite are found, largely to the exclusion of other oxidation products, in the first 20 micrometers of corroded steel below the air-steel interface, the conditions were selected to restrict corrosion to the top 20 micrometers to provide the controlled corrosion steel. In other words, the corrosion ranged from as little as 1 micrometer in some areas, to up to 20 micrometers in the disclocations. This was confirmed using Mössbauer spectroscopy. Further corrosion resulted in the goethite and akaganéite being against the rust-steel interface, with other oxidation products forming on the outer layers. This made the goethite and akaganéite less accessible to the next step in the treatment. Further, if the scratches were deeper than 5 to 10 micrometers, corrosion was deeper resulting in the goethite and akaganéite being against the rust-steel interface, with other oxidation products forming on the outer layers. This also made the goethite and akaganéite less accessible to the next step in the treatment.

In one embodiment, titanium dioxide crystals were added to the steel surface during the oxidation step (corroding step). The scratched steel plus the titanium dioxide were heated to 550° C. for one hour. Without being bound to theory, this temperature was selected as the titanium dioxide transforms from anatase to rutile at this temperature making it unstable and enhancing its alloying reaction with ferrous oxide. The resultant alloyed surface was then coated with silicon dioxide. Fine molten silicon dioxide particles were blow onto the alloyed surface using a gaseous flame. The flame was preferably a hydrogen-oxygen mixed gas. This provided the anti-corrosion steel which can be used in ships, rebar, bridge decks and the like.

In another embodiment, the titanium dioxide crystals were replaced with low iron oxide, iron doped titanium dioxide nanoparticles. The remainder of the treatment was as above. This provided the anti-corrosion steel which can be used in ships, rebar, bridge decks and the like.

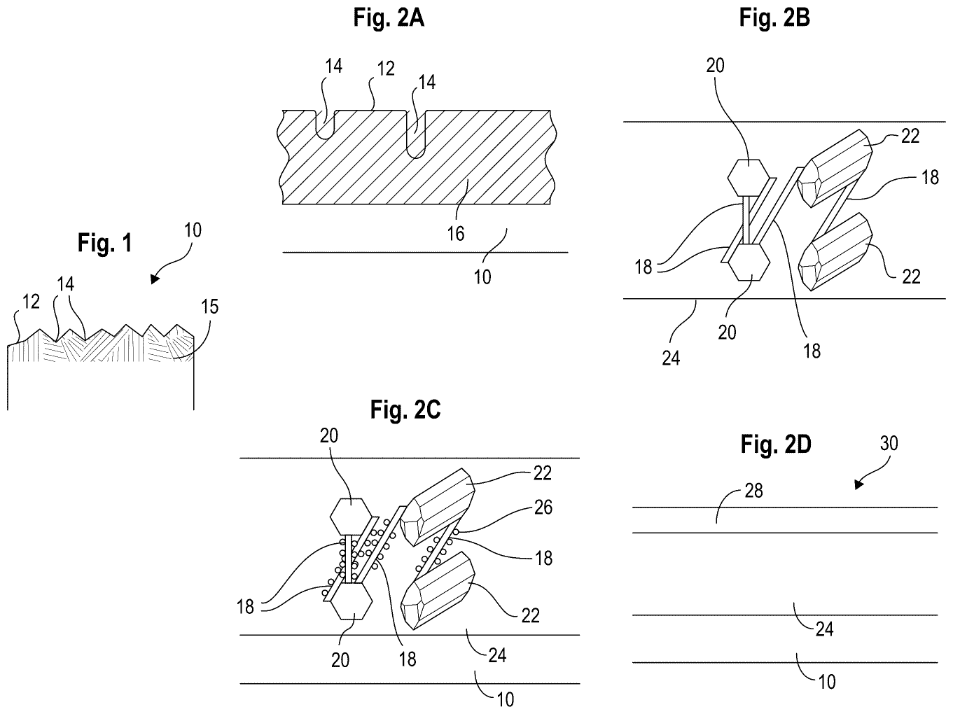

A schematic of the steps in producing anti-corrosion steel is shown in FIGS. 1 and 2A-D. As shown in FIG. 1, the outer surface 12 of the steel 10 includes scratches or abrasions 14 that are about 2.5 to ten micrometers deep, preferably five to ten micrometers deep. Scratching of the outer surface 12 precedes the next step of controlled corroding in all embodiments and results in dislocations in a dislocation zone 15 which penetrate the steel to twice the depth of the scratches 14.

As shown in FIG. 2A, controlled corrosion results in an outer layer 16 of goethite and akaganéite which fills the scratches 14, covers the outer surface 12, fills the dislocation zone 15 and is between 5 micrometers to 20 micrometers thick, preferably 10 micrometers to 20 micrometers thick. As shown in FIG. 2B, titanium dioxide 18 binds to the goethite 20 and akaganéite 22 in the outer layer 16 to provide an alloyed layer 24. As shown in FIG. 2C, the silicon dioxide 26 binds to the titanium dioxide in the alloyed layer 24. As shown in FIG. 2D the silicon dioxide forms a layer 28, which is an anti-corrosion layer 28 which coats the surface of the steel 10, to provide anti-corrosion steel, generally referred to as 30.

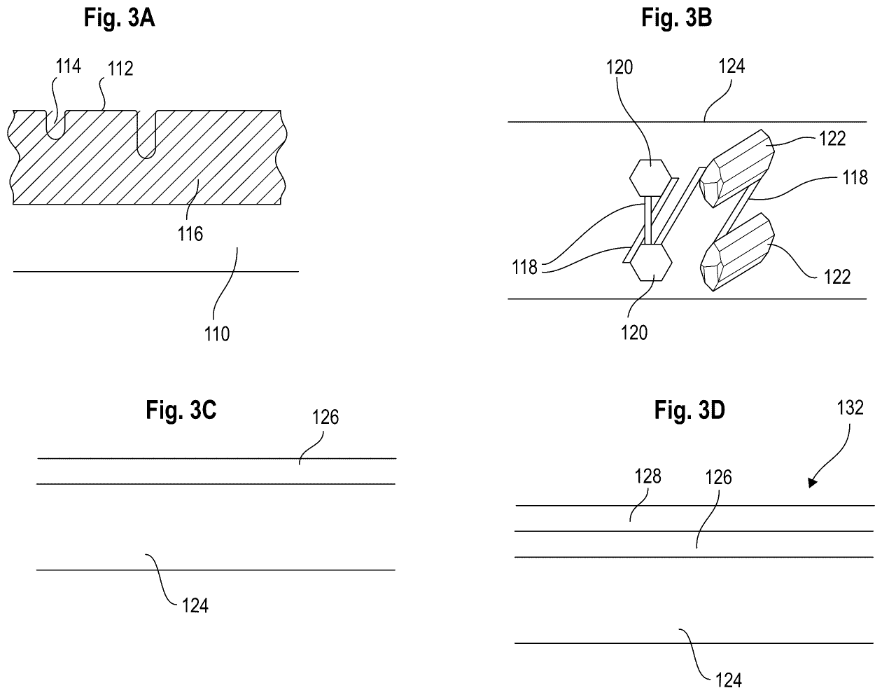

A schematic of the steps in producing anti-corrosion, anti-fouling steel is shown in FIGS. 3A-D. As shown in FIG. 3A, the outer surface 112 of the steel 110 includes the scratches 114 as shown in FIG. 1. Controlled corrosion results in an outer layer 116 of goethite and akaganéite which is between 5 micrometers to 20 micrometers, preferably 10 micrometers to 20 micrometers. As shown in FIG. 3B, titanium dioxide 118 binds to the goethite 120 and akaganéite 122 in the outer layer 116 to provide an alloyed layer 124. As shown in FIG. 3C, silicon dioxide 126 binds to the titanium dioxide in the alloyed layer 124. As shown in FIG. 3D, the silicon dioxide layer 126 is functionalized with low iron oxide, iron doped titanium dioxide nanoparticles 128 forming an anti-corrosion, anti-fouling layer 130 to produce the anti-corrosion, anti-fouling steel, generally referred to as 132.

In an alternative embodiment, the silicon dioxide was functionalized with iron doped titanium dioxide nanoparticles and then acid washed to provide low iron oxide, iron doped titanium dioxide nanoparticle functionalized silicon dioxide.

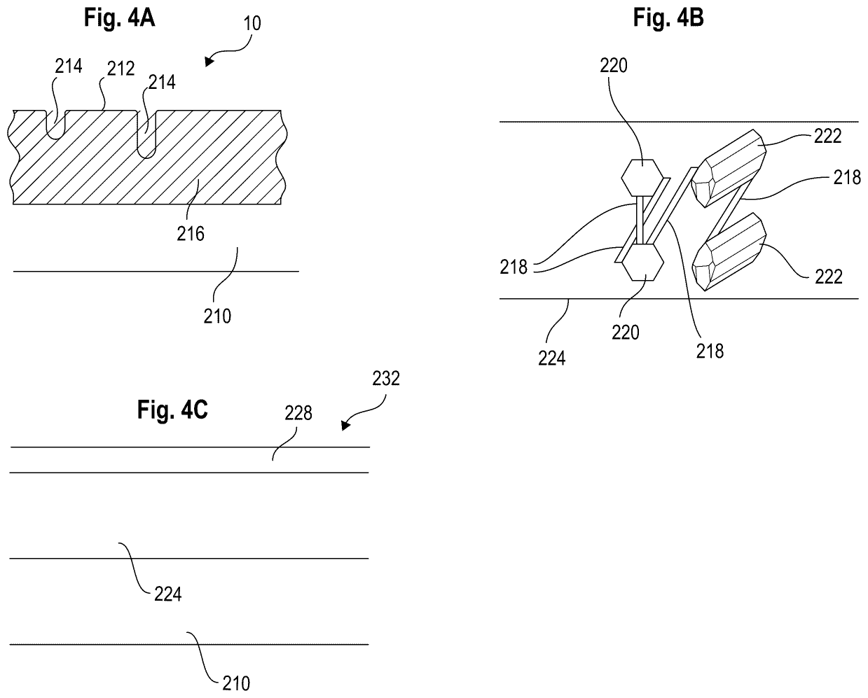

A schematic of an alternative method of producing anti-corrosion, anti-fouling steel is shown in FIGS. 4A-D. As shown in FIG. 4A, the outer surface 212 of the steel 210 includes the scratches 214 which are controlled to be between 5 and 10 micrometers deep. Controlled corrosion results in a layer 216 of goethite and akaganéite which is between 5 micrometers to 20 micrometers, preferably 10 micrometers to 20 micrometers. As shown in FIG. 4B, titanium dioxide 218 binds to the goethite 220 and akaganéite 222 in the layer 216 to provide an alloyed layer 224. As shown in FIG. 4C, silicon dioxide which is functionalized with low iron oxide, iron doped titanium dioxide nanoparticles binds to the alloyed layer 224, forming an anti-corrosion, anti-fouling layer 228 to provide the anti-corrosion, anti-fouling steel, generally referred to as 232.

In an alternative embodiment, the silicon dioxide was functionalized with iron doped titanium dioxide nanoparticles and then acid washed to provide low iron oxide, iron doped titanium dioxide nanoparticle functionalized silicon dioxide.

Three methods were used to functionalize the silicon dioxide in the anti-corrosion steel, resulting in the production of anti-corrosion, anti-fouling steel.

Iron-doped titanium dioxide nanoparticles were prepared by the sol-gel method using titanium isopropoxide (TTIP) as the precursor and ferric nitrate (Fe(NO3)3.9H2O) as the iron source. Firstly, the desired amount of ferric nitrate (0.25, 0.5, 1, 5 and 10 molar %) was dissolved in water and then the solution was added to 30 mL of anhydrous ethyl alcohol and stirred for 10 minutes. The acidity of the solution was adjusted to about pH 3 (about pH 2.5 to about pH 3.5) using HNO₃ (other acids could also be used), which produces better Fe doped TiO₂, i.e., incorporation of Fe into the TiO₂ nanocrystals. Secondly, TTIP was added dropwise to the solution. Then deionized water with the ratio of Ti:H2O (1:4) was added to the mixture. The solution was stirred for two hours, poured onto the anti-corrosion steel and then dried to form particles on the silicon dioxide. The combination of the particles and the anti-corrosion steel was then washed three times with deionized water. Next, the combination was calcined at 300° C. or slightly lower (as low as 275° C.) for one hour to adhere the iron-doped titanium dioxide nanoparticles to the silicon dioxide, thus producing functionalized silicon dioxide in the anti-corrosion steel. The anti-corrosion steel was washed in an HCl solution (acid washed) and then washed with deionized water three times. The acid washing was in a solution of about pH 2.5 to about pH 3.5, or about pH 4, with, preferably, a monoprotic acid, such as, for example, but not limited to acetic acid (CH3CO2H or HOAc), hydrochloric acid (HCl), hydroiodic acid (HI), hydrobromic acid (HBr), perchloric acid (HClO4), nitric acid (HNO3) or sulfuric acid (H2SO4), with HCl being the preferred. Through analysis, it was shown that the nanoparticles bind to the silicon dioxide in the anti-corrosion steel. The binding between the silicon dioxide and Fe doped TiO₂ is between the oxygen ions and not between Si and Ti ions. The nanoparticles form a thin film which has a surface that is substantially iron oxide free.

A second method of preparing the low iron oxide, iron-doped titanium dioxide functionalized silicon dioxide of the anti-corrosion steel is as follows:

Low iron oxide, iron-doped titanium dioxide nanoparticles were prepared by the sol-gel method using titanium isopropoxide (TTIP) as the precursor and ferric nitrate (Fe(NO₃)3.9H₂O) as the iron source. Firstly, the desired amount of ferric nitrate (0.25, 0.5, 1, 5 and 10 molar %) was dissolved in water and then the solution was added to 30 mL of anhydrous ethyl alcohol and stirred for 10 minutes. The acidity of the solution was adjusted to about pH 3 (about pH 2.5 to about pH 3.5) using HNO₃ (other acids could also be used), which produces better Fe doped TiO₂, i.e., incorporation of Fe into the TiO₂ nanocrystals. Secondly, TTIP was added dropwise to the solution. Then deionized water with the ratio of Ti:H₂O (1:4) was added to the mixture. The solution was stirred for two hours and then dried at 80° C. for two hours.

The powders were then washed three times with deionized water. Next, the powder was calcined at 400° C. for three hours. The calcined powder was stirred in an HCl solution (acid washed) and then washed with deionized water three times. The acid washing was in a solution of about pH 2.5 to about pH 3.5, or about pH 4, with, preferably, a monoprotic acid, such as, for example, but not limited to acetic acid (CH₃CO₂H or HOAc), hydrochloric acid (HCl), hydroiodic acid (HI), hydrobromic acid (HBr), perchloric acid (HClO₄), nitric acid (HNO₃) or sulfuric acid (H₂SO₄), with HCl being the preferred. The acid washing produced low iron oxide, iron-doped titanium dioxide. The low iron oxide, iron-doped titanium dioxide nanoparticles were suspended in water and the aqueous suspension was either sprayed onto the anti-corrosion steel, or at least the surface of the anti-corrosion steel was immersed in the aqueous suspension of low iron oxide. The combination of the silicon dioxide and the low iron oxide, iron-doped titanium dioxide nanoparticles was calcined at about 300° C. or slightly lower (as low as 275° C.) for four hours to adhere the low iron oxide, iron-doped titanium dioxide nanoparticles to the silicon dioxide in the anti-corrosion steel to produce functionalized silicon dioxide. Through analysis, it was shown that the nanoparticles bind to the silicon dioxide. The binding between the silicon dioxide and Fe doped TiO₂ is between the oxygen ions and not between Si and Ti ions. The nanoparticles form a thin film which has a surface that is substantially iron oxide free.

Regardless of the method of producing the low iron oxide, iron-doped titanium dioxide nanoparticle functionalized silicon dioxide, the acid washing was shown to remove a significant amount of iron oxide from the surface of the nanoparticles.

In an alternative embodiment, the anti-corrosion, anti-fouling steel is made by functionalizing the silicon dioxide of the anti-corrosion steel with iron-doped titanium dioxide nanoparticles. In this embodiment, the anti-corrosion, anti-fouling steel may be later treated with acid to reduce or eliminate the iron oxide to provide low iron oxide, iron doped titanium dioxide silicon dioxide of an anti-corrosion, anti-fouling steel.

A third method of preparing the low iron oxide, iron-doped titanium dioxide functionalized silicon dioxide was as follows: High purity iron of 99.999% (made by electrolytic refining) and titanium dioxide of 99.999% purity were mixed together as epi-layers on silicon dioxide particles in the anti-corrosion steel, using sputter deposition methods. Argon, nitrogen or xenon of 99.999% purity are used as the ionized gas. A thin epi layer of titanium dioxide is deposited followed by an epi layer of iron and a second epi layer of titanium dioxide. One method employed, which has some control over the amount of the deposition, involved depositing 100 nm titanium dioxide, then depositing 10 nm iron followed by depositing another 100 nm layer of titanium dioxide for an epi-layer thickness of 210 nm. This was then annealed to homogenize the iron within the titanium dioxide producing a material of 4.7 vol % iron doped titanium dioxide or 8.7 weight % iron doped titanium dioxide. Adjusting the thickness of the deposited iron epi-layer sandwiched between the titanium epi-layers allows for the synthesis of a range of concentrations of iron doping. This method does not require acid washing.

These three methods resulted in the production of anti-corrosion, anti-fouling steel. The anti-corrosion, anti-fouling steel can be used in ships to stop both corrosion and fouling.

In an alternative embodiment of all the embodiments, the silicon dioxide was supplied as fiberglass and was applied to the alloyed layer with rollers.

While the technology has been described in detail, such a description is to be considered as exemplary and not restrictive in character and is to be understood that it is the presently preferred embodiments of the present technology and is thus representative of the subject matter which is broadly contemplated by the present technology, and that all changes and modifications that come within the spirit of the disclosure are desired to be protected.

1. A method of manufacturing an anti-corrosion steel from a selected article of steel, the selected article of steel including an outer surface, the method comprising:
treating the outer surface to produce a dislocation zone in the selected article of steel that extends inward 10 to 20 micrometers from the outer surface; corroding the outer surface and the dislocation zone to a depth of no more than 20 micrometers from the outer surface to provide a controlled corroded steel layer comprising goethite and akaganéite; binding titanium dioxide to the goethite and akaganéite to provide an alloyed layer; and depositing silicon dioxide on the alloyed layer, thereby manufacturing the anti-corrosion steel.

2. The method of claim 1, wherein the treating is abrading the outer surface of the selected article of steel to provide scratched steel.

3. The method of claim 2, wherein the abrading is with 5 to 10 micrometer grit.

4. The method of claim 3, wherein the corroding and binding titanium dioxide are concomitant.

5. The method of claim 3, wherein the corroding precedes the binding of titanium dioxide.

6. The method of claim 5, further comprising cleaning at least one rust deposit on the outer surface of the selected article of steel prior to treating the outer surface to produce the dislocation zone.

7. The method of claim 6, wherein the anti-corrosion steel is also an anti-fouling steel, the method further comprising functionalizing the silicon dioxide of the anti-corrosion steel with iron doped titanium dioxide nanoparticles to provide anti-corrosion, anti-fouling steel.

8. The method of claim 7, further comprising acid washing the functionalized silicon dioxide of the anti-corrosion, anti-fouling steel to provide low iron oxide, iron doped titanium dioxide functionalized silicon dioxide.

9. The method of claim 6, wherein the anti-corrosion steel is also an anti-fouling steel, the method further comprising functionalizing the silicon dioxide of the anti-corrosion steel with low iron oxide, iron doped titanium dioxide.

10. The method of claim 9, wherein the functionalizing is by sputter deposition of high purity iron and titanium dioxide on the silicon dioxide.

11. An anti-corrosion steel, the anti-corrosion steel comprising, in order: a silicon dioxide layer; an alloyed layer including goethite, akaganéite and titanium dioxide which is bound to the goethite and the akaganéite; and an uncorroded inner layer.

12. The anti-corrosion steel of claim 11, wherein the alloyed layer is up to 20 micrometers in depth.

13. An anti-corrosion, anti-fouling steel, the anti-corrosion, anti-fouling steel comprising: an iron doped titanium dioxide functionalized silicon dioxide layer; an alloyed layer including goethite, akaganéite and titanium dioxide which is bound to the goethite and the akaganéite; and an uncorroded inner layer.

14. The anti-corrosion, anti-fouling steel of claim 13, wherein the alloyed layer is up to 20 micrometers in depth.

15. The anti-corrosion, anti-fouling steel of claim 14, wherein the iron doped titanium dioxide functionalized silicon dioxide is low iron oxide, iron doped titanium dioxide-silicon dioxide.
